(19) United States
(12) Patent Application Publication
(10) Pub. No.: US 2024/0128053 A1
(43) Pub. Date: Apr. 18, 2024

(54) MULTI-CHANNEL PULSE RF POWER SUPPLY APPARATUS

(71) Applicant: AS ENG CO., Yongin-si (KR)

(72) Inventor: HYUK SOO LEE, Yongin-si (KR)

(21) Appl. No.: 18/487,983

(22) Filed: Oct. 16, 2023

(30) Foreign Application Priority Data
Oct. 14, 2022 (KR) 10-2022-0132224

(51) Int. Cl. H01J 37/32

(52) U.S. Cl. CPC H01J 37/32146; H01J 37/32183; H01J 2237/327

(57) ABSTRACT

The present disclosure relates to a multi-channel pulsed RF power supply apparatus capable of applying same pulse RF signals to multiple electrodes, respectively, so as to generate consistent pulse plasma while carrying out a pulsed process in a single chamber, wherein the multi-channel pulsed RF power supply apparatus includes multiple electrodes provided in a single chamber; multiple RF signal generation units provided in the same number as the multiple electrodes to generate RF (Radio Frequency) signals having a predetermined frequency and phase; multiple RF signal application units that connect the multiple RF signal generation units and the multiple electrodes in a one-to-one manner to apply the RF signals to the multiple electrodes, respectively; multiple matching boxes provided in the multiple RF signal application units, respectively, to sense reflected waves transmitted from the electrodes and automatically perform impedance matching functions so that the reflected waves become “0”; and a multi-output pulse controller provided to be connected to each of the multiple RF signal generation units so as to provide multiple output pulse signals with the same pulse frequency, and a pulse width and a pulse delay that are configurable, to the multiple RF signal generation units.

### BACKGROUND OF THE INVENTION

### Field of the Invention

The present disclosure relates to a multi-channel pulse RF power supply apparatus, and more particularly, to a multi-channel pulsed RF power supply apparatus capable of applying same pulse RF signals to multiple electrodes, respectively, so as to generate consistent pulse plasma while carrying out a pulsed process in a single chamber.

### Background of the Related Art

Plasma is a highly ionized gas containing equal numbers of positive ions and electrons. Plasma discharge is used for gas excitation to generate activated gases containing ions, free radicals, atoms, and molecules. Activated gases are widely used in various fields and are used in a variety of semiconductor manufacturing processes for example, etching, deposition, cleaning, ashing, and the like to manufacture apparatuses such as integrated circuit apparatuses, liquid crystal displays, solar cells, and the like.

There are several plasma sources for generating plasma, and representative examples thereof include capacitive coupled plasma and inductive coupled plasma using radio frequency.

In general, as shown in FIG. 1, in such a plasma processing apparatus 1, an upper electrode 5 and a lower electrode 7 are disposed in parallel in a plasma chamber 3 configured as a vacuum chamber, and a substrate 2 (semiconductor wafer, glass substrate, etc.) to be processed is mounted on the lower electrode 7.

The upper electrode 5 is connected to a power supply source 10 and an impedance matcher 12 such that high frequencies are applied thereto from the power supply source 10. Then, electrons accelerated by a high-frequency electric field between the two electrodes, secondary electrons emitted from the electrodes, or heated electrons cause ionization collision with molecules in a processing gas to generate a plasma of the processing gas, thereby performing a desired microfabrication such as etching on a surface of the substrate using radicals or ions in the plasma.

However, as devices are reduced in size and highly integrated in semiconductor process technologies, a plasma process with higher efficiency, higher density, and lower bias is further required in capacitively coupled plasma processing apparatuses, and for this purpose, the trend today is to increase frequencies, which are used for the generation of plasma, as high as possible. Meanwhile, as the substrate to be processed is increased in size and the substrate is increased in diameter, plasma with a larger diameter is required, and chambers (processing containers) are becoming increasingly larger.

The problem here is that it is very difficult to make the plasma density uniform within a chamber processing space. That is, when RF frequencies for discharge are increased, the density at the center is maximized and the density at the edges is lowest approximately on the substrate, due to a wavelength effect in which standing waves are formed in the chamber, a skin effect in which high frequency waves are concentrated at the center on a surface of the electrode, or the like, resulting in non-uniform plasma density.

In order to solve the problem, technologies for making plasma density uniform by dividing the upper electrode 5 into multiple parts have been disclosed. Furthermore, as the construction of a clean room requires enormous costs, there is a need to quickly process a large number of substrates (semiconductor wafers, glass substrates, etc.) to be processed in a small area to reduce costs by increasing productivity. Therefore, a technology that allows simultaneous processing of a large number of substrates to be processed by providing multiple reactors in a single chamber is required.

Meanwhile, for microfabrication in the semiconductor manufacturing process, a new film added to the wafer must be finely deposited or etched, and for this purpose, the process is carried out little by little while repeatedly turning the plasma on and off.

This is called a pulsed process, in which the equipment may be manufactured in a method of using a pulse signal inside the RF power generator in case where the process is carried out on only one wafer in a single chamber, and only one RF power generator is used.

However, in recent years, as mentioned above, in case where the process is carried out on multiple wafers in a single chamber and the process is carried out by using a pulse signal inside each RF power generator while two or more RF power generators are used for each wafer, out-of-sync power is supplied to the chamber, thereby causing a serious problem that does not guarantee a consistent process progress.

### SUMMARY OF THE INVENTION

A technical problem to be solved by the present disclosure is to provide a multi-channel pulse RF power supply apparatus capable of applying same pulse RF signals to multiple electrodes, respectively, so as to generate consistent pulse plasma while carrying out a pulsed process in a single chamber.

In order to solve the foregoing technical problem, a multi-channel pulsed RF power supply apparatus according to an embodiment of the present disclosure may include multiple electrodes provided in a single chamber; multiple RF signal generation units provided in the same number as the multiple electrodes to generate RF (Radio Frequency) signals having a predetermined frequency and phase; multiple RF signal application units that connect the multiple RF signal generation units and the multiple electrodes in a one-to-one manner to apply the RF signals to the multiple electrodes, respectively; multiple matching boxes provided in the multiple RF signal application units, respectively, to sense reflected waves transmitted from the electrodes and automatically perform impedance matching functions so that the reflected waves become “0”; and a multi-output pulse controller provided to be connected to each of the multiple RF signal generation units so as to provide multiple output pulse signals with the same pulse frequency, and a pulse width and a pulse delay that are configurable, to the multiple RF signal generation units.

Furthermore, according to the present disclosure, the multi-output pulse controller may preferably provide a reference pulse signal or a pulse signal reflecting pulse width and pulse delay settings.

In addition, according to the present disclosure, the multi-output pulse controller may preferably include an interface unit capable of inputting control information; a multi-output pulse signal generation unit provided in connection with the interface unit to generate multiple output pulse signals with the same pulse frequency, and a pulse width and a pulse delay that are configurable based on the input control information; and a pulse signal output driver provided in connection with the multi-output pulse signal generation unit to transmit the multiple output pulse signals to the multiple RF signal generation units, respectively.

Moreover, according to the present disclosure, the multi-output pulse signal generation unit may preferably be configured with a central processing unit and a pulse generation apparatus.

According to a multi-channel pulse RF power supply apparatus of the present disclosure, there is an advantage in that same pulse RF signals can be applied to multiple electrodes, respectively, so as to generate consistent pulse plasma while carrying out a pulsed process in a single chamber.

### BRIEF DESCRIPTION OF THE DRAWINGS

FIG. 1 is a diagram schematically showing the configuration of a typical plasma processing apparatus.

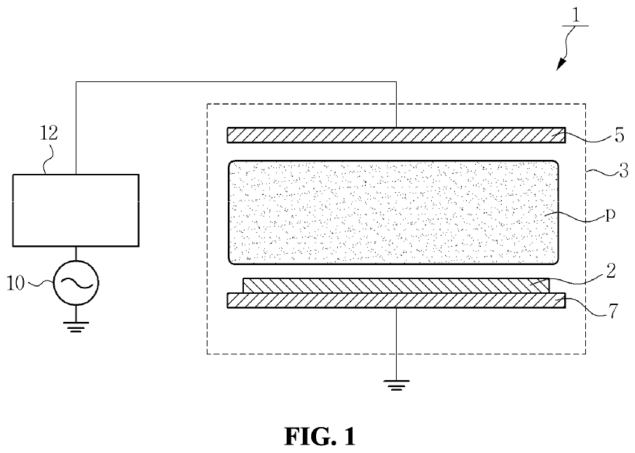

FIG. 2 is a diagram schematically showing the configuration of a multi-channel pulse RF power supply apparatus according to an embodiment of the present disclosure.

FIG. 3 is a block diagram showing the configuration of a multi-output pulse controller according to an embodiment of the present disclosure.

### DESCRIPTION OF SYMBOLS

100: Multi-channel pulse RF power supply apparatus according to an embodiment of the present disclosure
110: Multiple electrodes
120: Multiple RF signal generation units
130: Multiple RF signal application units
140: Multiple matching boxes
150: Multi-output pulse controller

### DETAILED DESCRIPTION OF THE PREFERRED EMBODIMENT

Hereinafter, a specific embodiment according to the present disclosure will be described in detail with reference to the accompanying drawings.

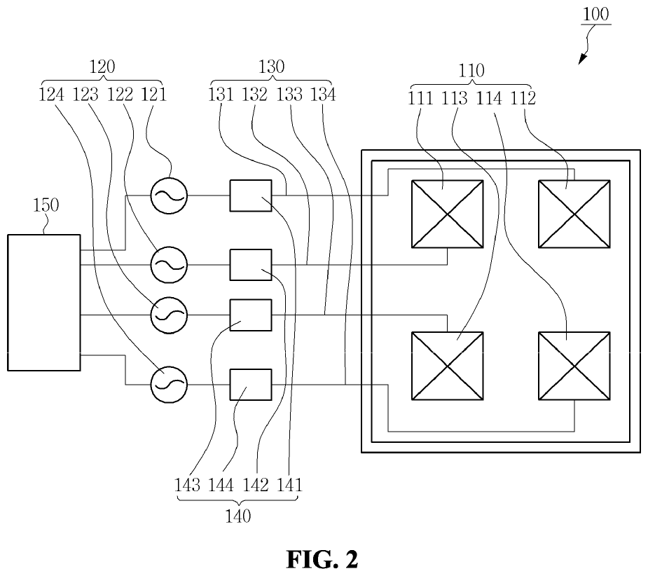

As shown in FIG. 2, a multi-channel pulse RF power supply apparatus 100 according to this embodiment includes multiple electrodes 110, multiple RF signal generation units 120, multiple RF signal application units 130, multiple matching boxes 140, and a multi-output pulse controller 150.

First, as shown in FIG. 2, the multiple electrodes 110 are components that are provided side by side in a single chamber 101 in a state of being spaced apart from one another, and the same RF power is applied thereto.

Next, as shown in FIG. 2, the multiple RF signal generation units 120 are components that are provided in the same number as the multiple electrodes 110 to generate RF (Radio Frequency) signals having a predetermined frequency and phase. The RF signal generation unit 120 may employ a generally known RF generator, and a detailed description thereof will be omitted.

Next, as shown in FIG. 2, the RF signal application unit 130 is a component that connects the multiple RF signal generation units 120 and the multiple electrodes 110 in a one-to-one manner to apply same RF signals to the multiple electrodes 110, respectively. The multiple RF signal application units 130 are preferably provided with the same connection conditions with the RF signal generation units 120, such as connection wire lengths, since it is suitable for applying the same RF signals.

Next, as shown in FIG. 2, the matching boxes 140 are components that are provided in the multiple RF signal application units 130, respectively, to sense reflected waves transmitted from the electrodes 110 and automatically perform impedance matching functions so that the reflected waves become “0”. The matching boxes 140 are respectively provided in the same number as the electrodes 110, and may have various structures capable of sensing reflected waves that are reflected and transmitted from the electrodes 110 in response to the outputs of the RF signal generation units 120 and automatically performing impedance matching functions so that the reflected waves become “0”.

Next, the multi-output pulse controller 150 is a component provided to be connected to each of the multiple RF signal generation units 120, as shown in FIG. 2 so as to provide multiple output pulse signals with the same pulse frequency, and a pulse width and a pulse delay that are configurable, to the multiple RF signal generation units 120. That is, the multi-output pulse controller 150 provides multiple output pulse signals with the same pulse frequency, a pulse width that is the same as or changeable from a reference pulse signal, and a pulse delay that is configurable, to the multiple electrodes 110.

Therefore, the multi-output pulse controller 150 preferably provides a reference pulse signal or a pulse signal with changed pulse width and pulse delay settings.

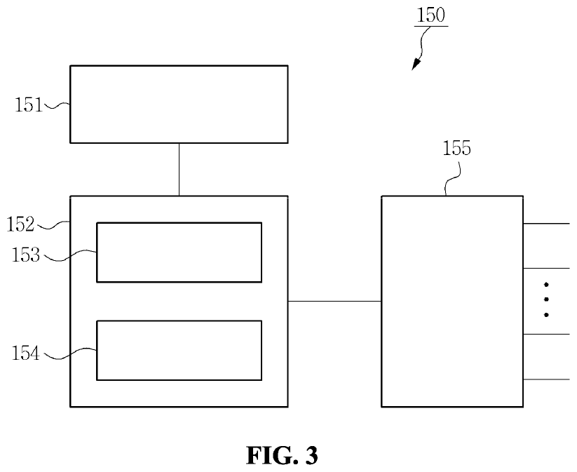

For this purpose, in this embodiment, the multi-output pulse controller 150 may include an interface unit 151, a multi-output pulse signal generation unit 152, and a pulse signal output driver 153, as shown in detail in FIG. 3. First, the interface unit 151 is a component capable of inputting control information to the multi-output pulse controller 150. Specifically, the interface unit 151 may be configured with a touch screen panel (TSP) capable of inputting control information.

Next, the multi-output pulse signal generation unit 152 is a component that is provided in connection with the interface unit 151, as shown in FIG. 3 to generate multiple output pulse signals with the same pulse frequency, and a pulse width and a pulse delay that are configurable based on the input control information. To this end, in this embodiment, the multi-output pulse signal generation unit 152 is preferably configured with a central processing unit 153 and a pulse generation apparatus 154, as shown in FIG. 3, or in a form in which the central processing unit 153 and the pulse generation apparatus 154 are integrated.

Furthermore, the pulse signal output driver 153 is a component that is provided in connection with the multi-output pulse signal generation unit 152, as shown in FIG. 3 to transmit the multiple output pulse signals to the multiple RF signal generation units 120, respectively. Accordingly, the number of output terminals of the pulse signal output driver 153 is configured according to the number of the multiple RF signal generation units 120 connected thereto.

What is claimed is:

1. A multi-channel pulse RF power supply apparatus comprising:
multiple electrodes provided in a single chamber;
multiple RF signal generation units provided in the same number as the multiple electrodes to generate RF (Radio Frequency) signals having a predetermined frequency and phase;
multiple RF signal application units that connect the multiple RF signal generation units and the multiple electrodes in a one-to-one manner to apply the RF signals to the multiple electrodes, respectively;
multiple matching boxes provided in the multiple RF signal application units, respectively, to sense reflected waves transmitted from the electrodes and automatically perform impedance matching functions so that the reflected waves become “0”; and
a multi-output pulse controller provided to be connected to each of the multiple RF signal generation units so as to provide multiple output pulse signals with the same pulse frequency, and a pulse width and a pulse delay that are configurable, to the multiple RF signal generation units.

2. The multi-channel pulse RF power supply apparatus of claim 1, wherein the multi-output pulse controller provides a reference pulse signal or a pulse signal reflecting pulse width and pulse delay settings.

3. The multi-channel pulse RF power supply apparatus of claim 2, wherein the multi-output pulse controller comprises:
an interface unit capable of inputting control information;
a multi-output pulse signal generation unit provided in connection with the interface unit to generate multiple output pulse signals with the same pulse frequency, and a pulse width and a pulse delay that are configurable based on the input control information; and
a pulse signal output driver provided in connection with the multi-output pulse signal generation unit to transmit the multiple output pulse signals to the multiple RF signal generation units, respectively.

4. The multi-channel pulse RF power supply apparatus of claim 3, wherein the multi-output pulse signal generation unit is configured with a central processing unit and a pulse generation apparatus.
